(19) United States
(12) Patent Application Publication
(10) Pub. No.: US 2025/0210621 A1
(43) Pub. Date: Jun. 26, 2025

(54) HIGH PERFORMANCE ANODE ELECTRODE INCLUDING SILICON FILM WITH CONTROLLED PRE-LITHIATION

(71) Applicant: GM GLOBAL TECHNOLOGY OPERATIONS LLC, Detroit, MI (US)

(72) Inventors: Qili SU, Shanghai (CN); Zhe LI, Shanghai (CN); Yong LU, Shanghai (CN); Haijing LIU, Shanghai (CN); Lijiao QUAN, Guangzhou City (CN); Lidan XING, Guangzhou City (CN)

(21) Appl. No.: 18/433,926

(22) Filed: Feb. 6, 2024

(30) Foreign Application Priority Data
Dec. 22, 2023 (CN) 202311787572.4

(51) Int. Cl. H01M 4/04; G01R 31/388; H01M 4/02; H01M 4/134; H01M 4/66; H01M 10/0525

(52) U.S. Cl. CPC H01M 4/0452; G01R 31/388; H01M 4/0423; H01M 4/134; H01M 2004/028; H01M 4/661; H01M 10/0525

(57) ABSTRACT

A method for manufacturing a battery cell includes providing an anode electrode including a nonplanar silicon film arranged on an anode current collector; immersing the anode electrode in a solution comprising lithium metal, an arene, and an organic solvent for a predetermined period to form a pre-lithiation coating on the nonplanar silicon film; and heating the anode electrode to remove the organic solvent and the arene after the predetermined period.

### CROSS-REFERENCE TO RELATED APPLICATIONS

This application claims the benefit of Chinese Patent Application No. 202311787572.4, filed on Dec. 22, 2023. The entire disclosure of the application referenced above is incorporated herein by reference.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells, and more particularly to an anode electrode with a silicon film with controlled pre-lithiation.

Electric vehicles (EVs) such as battery electric vehicles (BEVs), hybrid vehicles, and/or fuel cell vehicles include one or more electric machines and a battery system including one or more battery cells, modules, and/or packs. A power control system is used to control charging and/or discharging of the battery system during charging and/or driving.

Battery cells include cathode electrodes, anode electrodes, and separators. The cathode electrodes include a cathode active material layer (including cathode active material) arranged on a cathode current collector. The anode electrodes include an anode active material layer (including anode active material) arranged on an anode current collector.

### SUMMARY

A method for manufacturing a battery cell includes providing an anode electrode including a nonplanar silicon film arranged on an anode current collector; immersing the anode electrode in a solution comprising lithium metal, an arene, and an organic solvent for a predetermined period to form a pre-lithiation coating on the nonplanar silicon film; and heating the anode electrode to remove the organic solvent and the arene after the predetermined period.

In other features, the arene is selected from a group consisting of naphthalene, biphenyl, terphenyl, biphenylene, di phenyl methane, anthracene polyphenyl aliphatic hydrocarbon, polycyclic aromatic hydrocarbon, and/or a combination thereof. The arene is selected from a group consisting of 4,4′-dimethylbiphenyl, 2-methylbiphenyl, 3′,4,4′-tetramethylbiphenyl, 3′-dimethylbiphenyl, methyl naphthalene, 2-methylnaphthalene, 9,9-dimethyl-9H-fluorene, and/or combinations thereof. The lithium metal is selected from a group consisting of a lithium powder, a lithium foil, a lithium sheet, a lithium block, and/or combinations thereof. A molar ratio of the lithium metal and the arene in the solution is in a range from 0.2 to 2.0.

In other features, areal capacity of the pre-lithiation coating is in a range from greater than or equal to 0.5 mAh/cm² to less than 15 mAh/cm². The organic solvent is selected from a group consisting of 1,2-dimethoxyethane (DME), diglyme (DEGDME), and tetrahydrofuran (THF), 2-methyltetrahydrofuran (2-meTHF), tetrahydropyran (THP), and/or combinations thereof.

In other features, the method includes arranging A of the anode electrode, C cathode electrodes, and S separators in a battery stack where A, C, and S are integers greater than one. At least one of the A anode electrodes, the C cathode electrodes, and the S separators comprises solid electrolyte. At least one of the A anode electrodes, the C cathode electrodes, and the S separators comprises gel electrolyte.

In other features, the nonplanar silicon film comprises a plurality of columns. The plurality of columns have a major axis in a range from 0.5 μm to 80 μm and a minor axis in a range from 0.5 μm to 80 μm. The nonplanar silicon film is deposited onto the anode current collector using at least one of physical vapor deposition and magnetron sputter deposition. The nonplanar silicon film comprises one of pure silicon, silicon dioxide, and silicon mixed with at least one of graphite and carbon.

In other features, the anode current collector comprises roughened copper foil.

A method for manufacturing a battery cell includes providing an anode electrode including a nonplanar silicon film; selecting a lithiation level of the nonplanar silicon film based on a desired state of charge percentage (SOC %); using a lithiation curve and the desired SOC %, determining a voltage of the nonplanar silicon film; selecting a chemical potential of a solution including lithium, an arene, and an organic solvent based on the voltage of the nonplanar silicon film; and immersing the nonplanar silicon film in the solution for a predetermined period to form a pre-lithiation coating.

In other features, after the predetermined period, the method includes determining the SOC % of the anode electrode. The method includes arranging a lithium block in the solution and rotating a paddle in the solution during lithiation of the nonplanar silicon film wherein a rotational speed of the paddle is in a range from 5 to 1000 r/min. Areal capacity of the pre-lithiation coating is in a range from greater than or equal to 0.5 mAh/cm² to less than 15 mAh/cm². The predetermined period is in a range from 2 to 180 minutes at a temperature in a range from 25° C. to 80° C.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross sectional view of an example of a battery cell including anode electrodes with controlled pre-lithiated silicon active material according to the present disclosure;

FIG. 2A is a side cross sectional view of an example of an anode electrode with a planar silicon active material layer and a lithium metal film acting as a pre-lithiation layer;

FIG. 2B is a graph illustrating an example of voltage as a function of state of charge (SOC) for chemical pre-lithiation;

FIG. 3A is a side cross-sectional view of an example of an anode electrode including anode active material including nonplanar silicon film and a roughened copper current collector according to the present disclosure;

FIG. 3B is a perspective view of an example of columnar silicon of FIG. 3A;

FIG. 3C is a graph illustrating an example of voltage as a function of state of charge (SOC) for pre-lithiation of columnar silicon film and conventional planar silicon film;

FIG. 4 is a side cross-sectional view of an example of an anode electrode including anode active material including non-planar silicon film and a roughened copper current collector according to the present disclosure;

FIG. 5 is a graph illustrating an example of voltage as a function of state of charge (SOC) of a pre-lithiation curve for columnar silicon film and pre-lithiation potentials of various lithium-arene complex solutions according to the present disclosure;

FIG. 6 is a flowchart of an example of a method for controlling pre-lithiation of an anode electrode including columnar silicon film according to the present disclosure;

FIGS. 7A and 7B illustrate examples of methods for pre-lithiation of an anode electrodes including nonplanar silicon film according to the present disclosure;

FIGS. 8 and 9 are side cross sectional views of examples of battery cells with anode electrodes with controlled pre-lithiation according to the present disclosure;

FIG. 10A is a graph illustrating an example of voltage as a function of state of charge (SOC) for an anode electrode including columnar silicon film that is pre-lithiated according to the present disclosure;

FIG. 10B is a graph illustrating an example of voltage as a function of state of charge (SOC) during de-lithiation after pre-lithiation according to the present disclosure;

FIG. 11 is a side cross sectional view of an example of a battery cell according to the present disclosure;

FIG. 12 is a graph illustrating an example of voltage as a function of capacity for a battery cell without pre-lithiation and with controlled pre-lithiation according to the present disclosure;

FIG. 13 is a graph illustrating an example of voltage as a function of cycles for a battery cell without pre-lithiation and with controlled pre-lithiation according to the present disclosure; and

FIG. 14 is a graph illustrating an example of capacity retention as a function of cycles for a battery cell without pre-lithiation and with controlled pre-lithiation according to the present disclosure.

In the drawings, reference numbers may be reused to identify similar and/or identical elements.

### DETAILED DESCRIPTION

While battery cells according to the present disclosure are shown in the context of electric vehicles, the battery cells can be used in stationary applications and/or other applications.

An anode electrode according to the present disclosure includes a nonplanar silicon film with controlled pre-lithiation. The controlled pre-lithiation is enabled by chemical interaction between the nonplanar silicon film and a lithium-arene complex solution (e.g., lithium-naphthalene in an organic solvent). The unique initial lithiation behavior of the nonplanar silicon film (as compared to a planar silicon film) allows a lithium-arene complex solution (with different but lower chemical potential) to serve as a reductive regent to controllably lithiate the nonplanar silicon film and achieve a chemical potential equilibrium. In addition, by selecting the arene portion of the lithium-arene solution, other pre-lithiation levels can be achieved. The pre-lithiated nonplanar silicon film delivers increased cell capacity and enhanced cell cyclability.

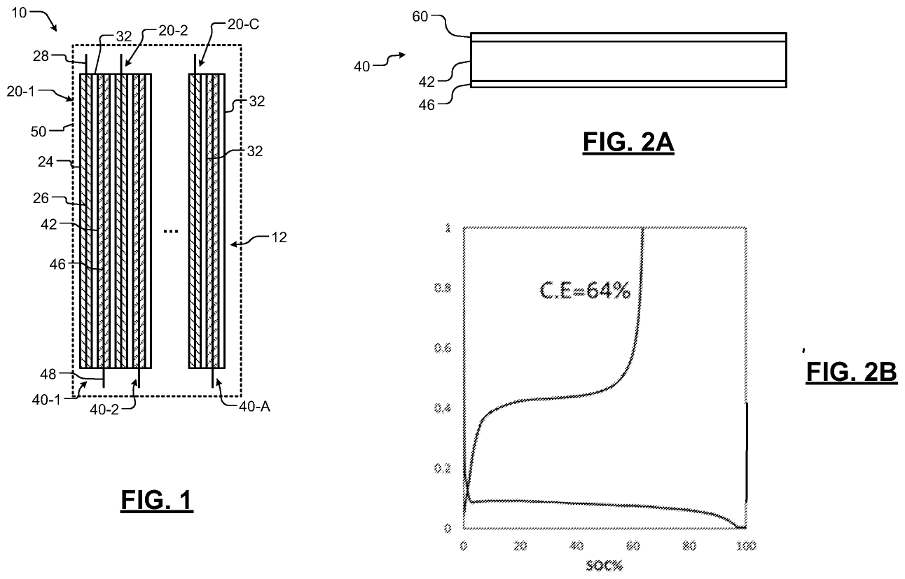

Referring now to FIG. 1, a battery cell 10 includes C cathode electrodes 20, A anode electrodes 40, and S separators 32 arranged in a predetermined sequence in a battery cell stack 12, where C, S and A are integers greater than zero. The C cathode electrodes 20-1, 20-2, . . . , and 20-C include cathode active material layers 24 arranged on one or both sides of a cathode current collector 26.

During charging/discharge, the A anode electrodes 40 and the C cathode electrodes 20 exchange lithium ions. The A anode electrodes 40-1, 40-2, . . . , and 40-A include anode active material layers 42 arranged on one or both sides of the anode current collectors 46. The anode active material layers 42 include nonplanar silicon film that has been controllably pre-lithiated. In some examples, the cathode active material layers 24 comprise coatings including one or more active materials, one or more conductive additives, and/or one or more binder materials that are applied to the current collectors.

In some examples, the cathode current collector 26 comprises metal foil, metal mesh, perforated metal, 3 dimensional (3D) metal foam, and/or expanded metal. In some examples, the anode current collector 46 comprises roughened metal foil (e.g., copper foil). In some examples, the current collectors are made of one or more materials selected from a group consisting of copper, stainless steel, brass, bronze, zinc, aluminum, and/or alloys thereof. External tabs 28 and 48 are connected to the current collectors of the cathode electrodes and anode electrodes, respectively, and can be arranged on the same or different sides of the battery cell stack 12. The external tabs 28 and 48 are connected to terminals of the battery cells.

Referring now to FIG. 2A, when the anode active material layer 42 of the anode electrode 40 includes planar silicon electrode, a pre-lithiation layer 60 comprising a lithium film can be formed on the anode active material layer 42. For example, stable lithium metal powder (SLMP) can be used to form the anode active material layer 42. Pre-lithiation of the anode active material layer 42 can greatly improve energy density and cycle life of the battery cell. However, it is difficult to control the pre-lithiation level. High lithium reactivity occurs during fabrication and within the electrolyte (which leads to low pre-lithiation efficiency). Currently a minimum thickness of the lithium film is limited to 20 μm using current manufacturing methods. As a result, pre-lithiation capacity is always higher than 5 mAh/cm². In addition, there is spatial inhomogeneity of the reaction.

Referring now to FIG. 2B, an initial pre-lithiation cycle at 0.05C is shown. Pre-lithiation of the anode active material layer 42 using a chemical solution such as a reductive lithium-organic compound (e.g., lithium-naphthalene) is not able to lithiate the silicon powder electrode (e.g., lithium-naphthalene). While a few combinations of reduction lithium-organic compounds (e.g., lithium-2-methylnaphthalene) can lithiate the planar silicon electrode, it is hard to accurately pre-lithiate the electrode by simply controlling the lithiation exposure time and temperature (since the lithiation curve is almost flat).

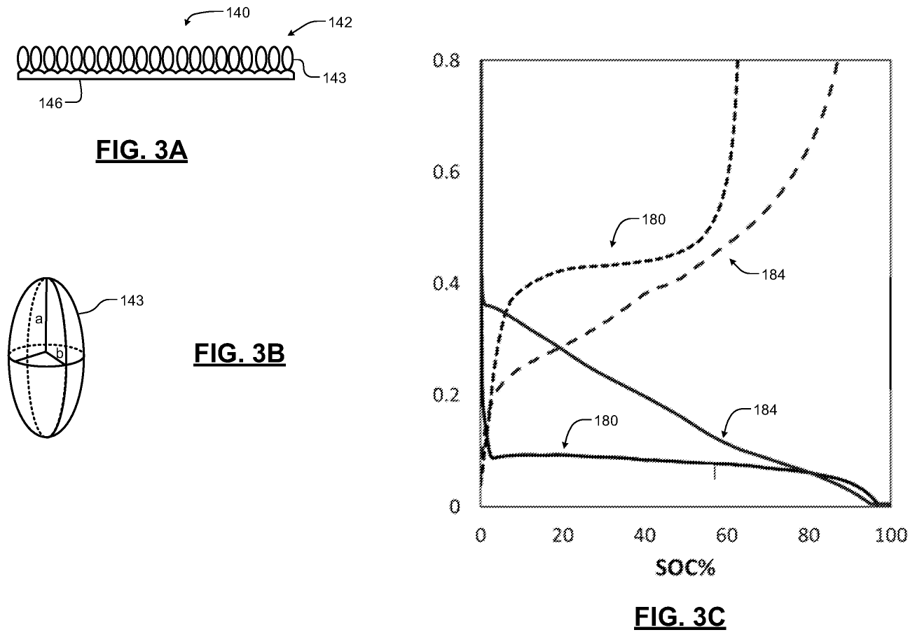

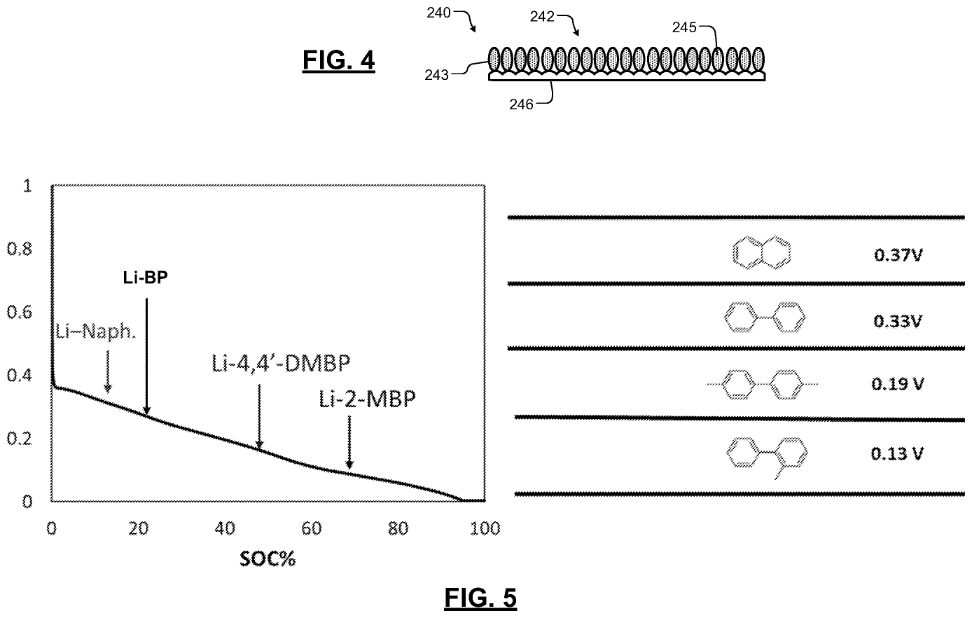

Referring now to FIGS. 3A to 3C, the silicon anode active material layer can include nonplanar silicon film (e.g., columnar) instead of planar conventional silicon electrode. Columnar silicon film has different initial lithiation behavior than planar silicon electrode. In FIGS. 3A and 3B, an anode electrode 140 includes anode active material 142 including nonplanar silicon film 143 (e.g., columnar silicon film) arranged on a current collector 146 (e.g., a roughened copper current collector).

In some examples, the nonplanar silicon film includes a plurality of silicon columns. A cross sectional shape of the silicon columns in FIG. 3B is ellipsoidal. In some examples, the silicon columns have an elliptical cross-sectional shape with dimensions a and b. Dimension b corresponds to a semi-minor axis and dimension a corresponds to a semi-major axis. In some examples, a is in a range from 0.5 to 80 μm (e.g., 8 μm). In some examples, b is in a range from 0.5 to 80 μm (e.g., 8 μm). In some examples, the silicon columns are fabricated using physical vapor deposition (PVD). In some examples, the active anode material 22 includes silicon columns, although Si particles, Si wires, Si flakes, porous Si or other Si material can be used.

Further details relating to manufacturing of the columnar silicon film can be found in commonly-assigned U.S. patent application Ser. No. 18/363,036 filed on Aug. 1, 2023 (GM Docket No. P103060), which is hereby incorporated herein by reference. In some examples, the silicon film comprises pure silicon. In other examples, a pure silicon film with an amorphous phase is prepared using magnetron sputter deposition. In other examples, the silicon film can include silicon-based materials such as silicon dioxide (SiOₓ). In other examples, the silicon is blended with other materials such as graphite and/or carbon.

In FIG. 3C, the lithiation curve of columnar silicon film at 182 is approximately linear with a slope corresponding to y=−kx (for an initial cycle at 0.05C). The lithiation curve of columnar silicon film is matched with conventional reductive lithium-organic compounds (e.g., lithium-naphthalene). In other words, control of voltage equals control of SOC %. However, the lithiation curve for conventional planar silicon electrodes is relatively flat (or near zero slope) for most SOC % values (which means that pre-lithiation is not easily controlled).

Referring now to FIG. 4, an anode electrode 240 according to the present disclosure includes anode active material 242 including columnar silicon film 243 and an anode current collector 246. In some examples, the anode current collector 246 is roughened and the highest point of the anode current collector 20 minus the lowest point of the current collector) is in a range from 0.1 μm to 20 μm. A pre-lithiation coating 245 is realized by a chemical interaction between the columnar silicon film and a solution including a lithium-arene and an organic solvent (e.g., an ether solvent such as 1,2-dimethoxyethane (DME)).

The columnar structure of the silicon film has increased surface interface area to facilitate charge transfer and low porosity to increase energy density. In some examples, the pre-lithiation coating 245 has areal capacity in a range from 0.5 to less than 20 mAh/cm². In some examples, the pre-lithiation coating 245 has areal capacity in a range from greater than or equal to 0.5 mAh/cm² to 15 mAh/cm². In some examples, the pre-lithiation coating 245 has areal capacity in a range from greater than or equal to 0.5 mAh/cm² to less than 5 mAh/cm². The anode active material has enhanced electron conductivity after pre-lithiation and extra active lithium is provided for the battery cell. The lithiation level of LiₓSi (0<x<4.4) is controlled by the chemical potential of the lithium-arene solution.

The pre-lithiation coating 245 has a thickness d2 that is greater than the thickness d1 of the columnar silicon film. Pre-lithiation within the lithium-arene solution forms a solid electrolyte interface (SEI) that reduces the electrolyte decomposition and active lithium consumption within the battery cell. The thickness of SEI is range from 1 nm to 1 μm. The roughened surface of the anode current collector strengthens adhesion between the anode current collector and the LiₓSi columns.

In some examples, the lithium-arene complex solution comprises a lithium-arene component in an organic solvent. In some examples, the lithium-arene component comprises 0.1 to 5 mol/L in the organic solvent. A source of lithium comprises at least one of a lithium powder, a lithium foil, a lithium sheet, a lithium block, and/or combinations thereof.

In some examples, the arene comprises at least one of an arene product and a hydrocarbon-substituted arene product. In some examples, the arene product is selected from a group consisting of naphthalene, biphenyl, terphenyl, biphenylene, di phenyl methane, anthracene polyphenyl aliphatic hydrocarbon, polycyclic aromatic hydrocarbon, and/or a combination thereof. In some examples, the hydrocarbon-substituted arene products are selected from a group consisting of 4,4′-dimethylbiphenyl, 2-methylbiphenyl, 3′,4,4′-tetramethylbiphenyl, 3′-dimethylbiphenyl, methyl naphthalene, 2-methylnaphthalene, 9,9-dimethyl-9H-fluorene, and/or combinations thereof. In some examples, the molar ratio of the lithium/arene is in a range from 0.2 to 2.0.

In some examples, the organic solvent comprises an ether solvent and/or a furan solvent. In some examples, the organic solvent is selected from a group consisting of 1,2-dimethoxyethane (DME), diglyme (DEGDME), and tetrahydrofuran (THF), 2-methyltetrahydrofuran (2-meTHF), tetrahydropyran (THP), and/or combinations thereof.

Referring now to FIG. 5, a graph illustrates an example of voltage as a function of state of charge (SOC) and pre-lithiation potentials of some of the lithium-arene complex solutions. For example only, lithium-naphthalene has an E_{1/2} potential of 0.37V, lithium-biphenyl has an E_{1/2} potential of 0.33V, lithium-dimethyl biphenyl has an E_{1/2} potential of 0.19V, and lithium-methyl biphenyl has an E_{1/2} potential of 0.13V. The lithium-arene complex can be selected for the silicon film anode that is used and the desired SOC %.

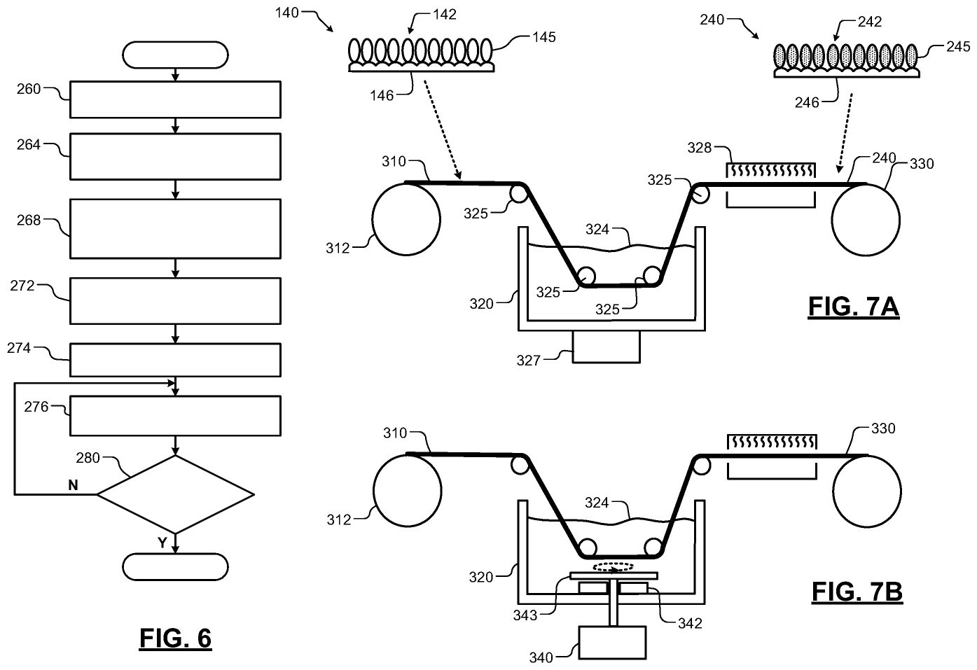

Referring now to FIG. 6, a method for pre-lithiation of a silicon anode electrode is shown. At 260, an anode electrode including a silicon film arranged on an anode current collector is provided. At 264, the lithiation level of the silicon film is selected (xSOC %). At 268, the voltage corresponding to the xSOC % is determined from a corresponding lithiation curve. At 272, the chemical potential of the lithium-arene solution is determined. The chemical potential is based on lithium concentration, the arene, and the organic solvent that are selected at 274. At 276, the anode electrode is immersed in the lithium-arene solution. At 280, the method determines whether the silicon film on the anode electrode has the designed SOC %. If 280 is false, the method returns to 276. In some examples, the anode electrode is weighed to determine whether a mass m2 of the anode electrode is equal to a desired mass m1 (e.g., having the desired LiₓSi composition).

Referring now to FIGS. 7A and 7B, methods for pre-lithiation of anode electrodes including silicon are shown. In FIG. 7A, a silicon anode electrode 310 is provided by a roll 312 and guided by one or more guide rollers 325 into a tank 320 including a lithium-arene solution 324. The silicon anode electrode 310 is immersed for a period sufficient for chemical equilibrium. Afterwards, the silicon anode electrode with the coating passes through a heater 328 to remove the solvent and the arene and then collected on a roller 330.

In FIG. 7B, in some examples, a lithium block 342 is arranged in the lithium-arene solution 324 to compensate for lithium that is used. In some examples, a paddle 243 in the lithium-arene solution 324 is rotated by an actuator 343 such as a motor to mix the solution. A heater 327 can be used to control the temperature of the solution during pre-lithiation to a predetermined temperature range.

As can be appreciated, the anode electrode can be manufactured by a roll-to-roll process with controlled pre-lithiation of the silicon film. The lithiation of silicon film anode is homogeneous through a solution chemical reaction. The pre-lithiation level is controlled by the chemical potential of the lithium-arene complex solution. The solvent and the arene components are removed by evaporation under high temperature (e.g., temperature greater than 100° C.).

In some examples, the lithium-arene solution reaches a saturation concentration. In some examples, the lithium block is used to mitigate active lithium concentration loss during pre-lithiation. Preferably, the rotating speed of the paddle 343 in the pre-lithiation tank in a range from 5 to 1000 r/min. In some examples, the period of the pre-lithiation is in a range from 2 to 180 minutes. In some examples, the period of the pre-lithiation is in a range from 5 to 50 minutes. In some examples, the period of the pre-lithiation is in a range from 8 to 40 minutes. In some examples, the temperature of the pre-lithiation is in a range from 25° C. to 80° C. In some examples, the temperature of the pre-lithiation is in a range from 60° C. to 80° C.

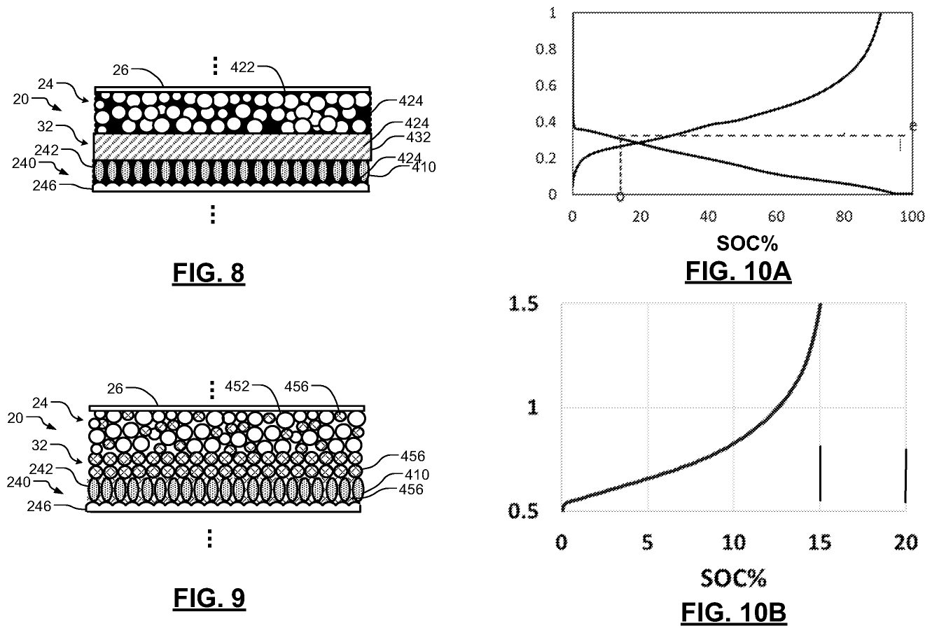

Referring now to FIGS. 8 and 9, the silicon anode film with controllable pre-lithiation can be used with battery cells using solid electrolyte, liquid electrolyte, gel electrolyte, and/or combinations thereof. In FIG. 8, the anode electrode 240 includes the anode active material layer 242 including silicon active material 410 with controlled pre-lithiation, the anode current collector 246 (e.g., a roughened copper anode current collector), and a liquid or gel electrolyte 424. The separator 32 includes a film 432 such as a polypropylene (PP) or polyethylene (PE) separator and the liquid or gel electrolyte 424. The cathode electrode 20 includes the cathode active material 24 (e.g., LiMn₂O₆) and the liquid or gel electrolyte 424.

In FIG. 9, the anode electrode 240 includes the anode active material layer 242 including silicon active material with controlled pre-lithiation, the anode current collector 246 (e.g., a roughened copper anode current collector), and a solid electrolyte 456 (e.g., sulfide electrolyte such as Li₆PS₅Br). The separator 32 includes the solid electrolyte 456. The cathode electrode 20 includes the cathode active material 24 and the solid electrolyte 456.

Referring now to FIG. 10A, a graph illustrates an example of voltage as a function of state of charge (SOC) for an anode electrode including silicon film. If approximately 15% SOC is the designed pre-lithiation level, the lithium-arene solution may include lithium-naphthalene and an organic solvent such as DME. In FIG. 10B, a graph illustrates an example of voltage as a function of state of charge (SOC) during de-lithiation after pre-lithiation in FIG. 10A. The pre-lithiation forms the solid electrolyte interface (SEI) layer within the lithium-arene that reduces electrolyte decomposition and active lithium consumption within the battery cell.

Referring now to FIGS. 11-14, the higher performance pre-lithiated silicon anode electrodes enables higher discharge and columbic efficiency. In FIG. 11, the anode electrode 240 includes the anode active material layer 242 including silicon active material 510 with controlled pre-lithiation, the anode current collector 246 (e.g., a roughened copper anode current collector), and a gel electrolyte 524 (e.g., 0.8MLiTFSI+0.8MLiBF₄ in FEC/GBL=3:7 with 5% PVDF-HFP). The separator 32 includes a solid electrolyte 556 (e.g., LATP) and/or a film 554 such as a polypropylene (PP) or polyethylene (PE) and the gel electrolyte 524. The cathode electrode 20 includes the cathode active material 24 (e.g., a blend of LMFP and LiMn₂O₆) and the gel electrolyte 524.

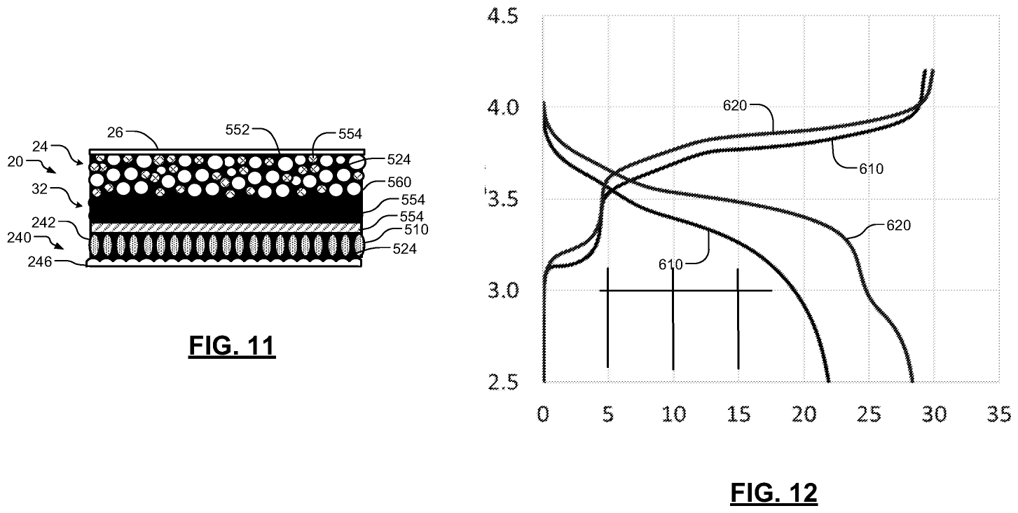

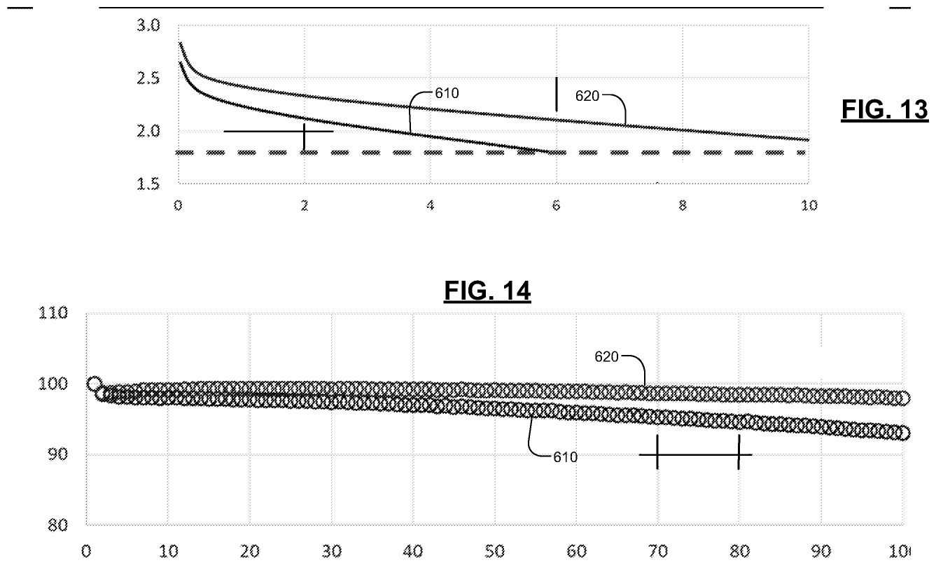

In FIG. 12, as compared to a battery cell without pre-lithiation at 610, a battery cell with pre-lithiation at 620 has higher capacity delivery and superior initial columbic efficiency (e.g., greater than 94.8%). In FIG. 13, the battery cell with pre-lithiation at 620 has improved cold cranking at −18° C., 80% SOC, and 10C pulse for more than 10 s above 1.8V as compared to the battery cell without pre-lithiation at 610. In FIG. 14, the battery cell with pre-lithiation at 620 has improved cycling performance as compared to the battery cell without pre-lithiation at 610. The battery cell with pre-lithiation at 620 has more than 97.8% capacity retention after 100 cycles.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A method for manufacturing a battery cell comprising:
providing an anode electrode including a nonplanar silicon film arranged on an anode current collector;
immersing the anode electrode in a solution comprising lithium metal, an arene, and an organic solvent for a predetermined period to form a pre-lithiation coating on the nonplanar silicon film; and
heating the anode electrode to remove the organic solvent and the arene after the predetermined period.

2. The method of claim 1, wherein the arene is selected from a group consisting of naphthalene, biphenyl, terphenyl, biphenylene, di phenyl methane, anthracene polyphenyl aliphatic hydrocarbon, polycyclic aromatic hydrocarbon, and/or a combination thereof.

3. The method of claim 1, wherein the arene is selected from a group consisting of 4,4′-dimethylbiphenyl, 2-methylbiphenyl, 3′,4,4′-tetramethylbiphenyl, 3′-dimethylbiphenyl, methyl naphthalene, 2-methylnaphthalene, 9,9-dimethyl-9H-fluorene, and/or combinations thereof.

4. The method of claim 1, wherein the lithium metal is selected from a group consisting of a lithium powder, a lithium foil, a lithium sheet, a lithium block, and/or combinations thereof.

5. The method of claim 1, wherein a molar ratio of the lithium metal and the arene in the solution is in a range from 0.2 to 2.0.

6. The method of claim 1, wherein areal capacity of the pre-lithiation coating is in a range from greater than or equal to 0.5 mAh/cm² to less than 15 mAh/cm².

7. The method of claim 1, wherein the organic solvent is selected from a group consisting of 1,2-dimethoxyethane (DME), diglyme (DEGDME), and tetrahydrofuran (THF), 2-methyltetrahydrofuran (2-meTHF), tetrahydropyran (THP), and/or combinations thereof.

8. The method of claim 1, further comprising arranging A of the anode electrode, C cathode electrodes, and S separators in a battery stack where A, C, and S are integers greater than one.

9. The method of claim 8, wherein at least one of the A anode electrodes, the C cathode electrodes, and the S separators comprises solid electrolyte.

10. The method of claim 8, wherein at least one of the A anode electrodes, the C cathode electrodes, and the S separators comprises gel electrolyte.

11. The method of claim 1, wherein the nonplanar silicon film comprises a plurality of columns.

12. The method of claim 11, wherein the plurality of columns have a major axis in a range from 0.5 μm to 80 μm and a minor axis in a range from 0.5 μm to 80 μm.

13. The method of claim 1, wherein the nonplanar silicon film is deposited onto the anode current collector using at least one of physical vapor deposition and magnetron sputter deposition.

14. The method of claim 1, wherein the nonplanar silicon film comprises one of pure silicon, silicon dioxide, and silicon mixed with at least one of graphite and carbon.

15. The method of claim 1, wherein the anode current collector comprises roughened copper foil.

16. A method for manufacturing a battery cell, comprising:
providing an anode electrode including a nonplanar silicon film;
selecting a lithiation level of the nonplanar silicon film based on a desired state of charge percentage (SOC %);
using a lithiation curve and the desired SOC %, determining a voltage of the nonplanar silicon film;
selecting a chemical potential of a solution including lithium, an arene, and an organic solvent based on the voltage of the nonplanar silicon film; and
immersing the nonplanar silicon film in the solution for a predetermined period to form a pre-lithiation coating.

17. The method of claim 16, further comprising, after the predetermined period, determining the SOC % of the anode electrode.

18. The method of claim 16, further comprising arranging a lithium block in the solution and rotating a paddle in the solution during lithiation of the nonplanar silicon film wherein a rotational speed of the paddle is in a range from 5 to 1000 r/min.

19. The method of claim 18, wherein areal capacity of the pre-lithiation coating is in a range from greater than or equal to 0.5 mAh/cm² to less than 15 mAh/cm².

20. The method of claim 16, wherein the predetermined period is in a range from 2 to 180 minutes at a temperature in a range from 25° C. to 80° C.
